(19) United States
(12) Patent Application Publication
(10) Pub. No.: US 2008/0184829 A1
(43) Pub. Date: Aug. 7, 2008

(54) VIBRATOR COUNTERWEIGHT ASSEMBLY FOR USE IN AN ELECTRONIC DEVICE AND METHOD OF FORMING SAME

(75) Inventors: Peter B. Gilmore, Plantation, FL (US); David E. Reiff, Southwest Ranches, FL (US); Jignesh G. Sharda, Sunrise, FL (US)

Correspondence Address: MOTOROLA, INC, 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/670,276

(22) Filed: Feb. 1, 2007

(51) Int. Cl. F16H 33/00; H01S 4/00; H04B 1/38; H05K 1/18

(52) U.S. Cl. 74/61; 29/592.1; 361/748; 455/73

(57) ABSTRACT

A vibrator counterweight assembly for use in an electronic device includes an electric motor (201) and shaft (203) for providing rotational movement adjacent to a substrate (209). An eccentric counterweight (205) is connected to the electric motor (201) through the shaft (203). A bend reduction stop (207) is attached to the eccentric counterweight (205) and works to prevent damage to the shaft (203) during a high stress loading condition on the electronic device.

### FIELD OF THE INVENTION

The present invention relates generally to a vibration assembly used in an electronic device and more particularly to the use of a vibrator counterweight used in the vibration assembly.

### BACKGROUND

Vibratory motors are commonly used in connection with electronic devices to tactically notify a user of an alert condition. Most often the motor is used to vibrate the housing of a cellular telephone when an incoming voice call or text message is received. In operation, the motor is mounted within the housing of the electronic device where an off-center or eccentric counterweight is connected with the motor's drive shaft such that activation of the motor causes a vibration due to the rotation of the weight. FIG. 1 is a diagram illustrating a side and end view of the motor and eccentric weight assembly 100 as used in the prior art. A motor 101 uses a shaft 103 to rotate an eccentric weight 105. The weight 105 rotates such that it clears a substrate such as a printed circuit board (PCB) 107 or other housing. FIG. 2 is a diagram illustrating a side and end view of the motor and eccentric weight assembly 200 as shown in FIG. 1 however the eccentric weight 105′ attached to the shaft 103′ is shown in an elevated position during rotation such that there is a greater degree of clearance with the printed circuit board 107.

A problem can occur with the motor and eccentric weight assembly when the assembly is dropped or otherwise subjected to some high load or stress condition within the electronic device. Under these conditions, it is often possible to bend or deform the shaft so that the eccentric weight is out of longitudinal alignment with the motor. FIG. 3 is a diagram illustrating a side and end view of the motor and eccentric weight assembly 300 that is damaged after the assembly is subjected to a high stress condition. In this example, the shaft 103″ has been bent or deformed due to the forces applied as a result of the fall or other high stress event. FIG. 3 shows the eccentric weight 105″ bent in a direction toward the PCB 107 such that it may sometimes contact the PCB 107 and prevent it from rotating in a normal manner. In this situation, it is possible the vibration feature of the electronic device using such a weight may no longer operate and will have to be repaired in order to restore this type of functionality.

Accordingly, the need exists to provide a vibrator counterweight assembly that can sustain the high stresses, loads and other forces without damage when subjected to a fall or other stress condition when used within an electronic device.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 illustrates a side and end views of a vibrator and counterweight assembly used in the prior art showing an eccentric weight positioned close to a printed circuit board during rotation.

FIG. 2 illustrates a side and end views of a vibrator and counterweight assembly as shown in FIG. 1 where the eccentric weight is positioned distant from the printed circuit board during rotation.

FIG. 3 illustrates side and end views of a vibrator and counterweight assembly as shown in FIG. 2 where the eccentric weight is damaged to restrict movement of the eccentric weight to prevent proper vibration.

FIG. 4 illustrates side and end views of a vibration motor and counterweight assembly using a bend reduction stop directed away from the printed circuit board in accordance with an embodiment of the invention.

FIG. 5 illustrates side and end views of a vibration motor and counterweight assembly as in FIG. 4 with a bend reduction stop directed toward the printed circuit board in accordance with an embodiment of the invention.

FIG. 6 illustrates side and end views of a vibration motor and counterweight assembly as in FIG. 5 after a high stress event with a bend reduction stop limiting the stress on the eccentric weight when contacting the printed circuit board in accordance with an embodiment of the invention.

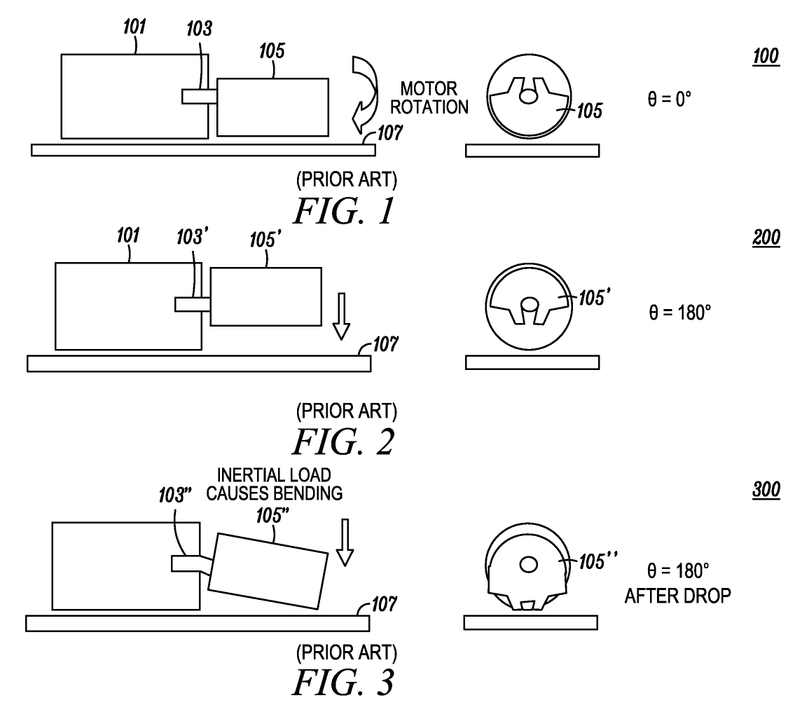

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a vibrator counterweight assembly. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

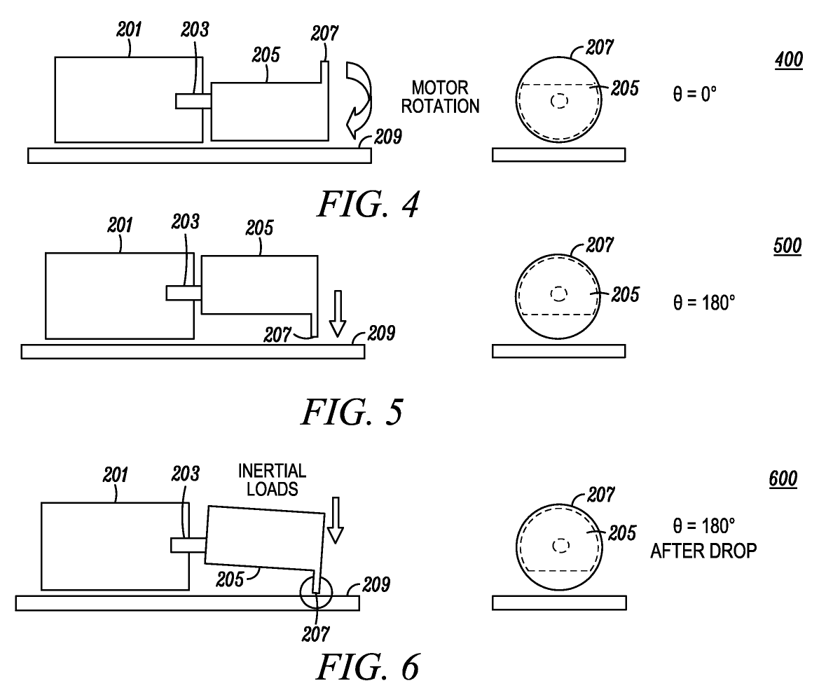

FIG. 4 illustrates side and end view of the vibrator counterweight assembly 400 where a motor 201 utilizes a shaft 203 to connect to an eccentric weight 205. The eccentric weight 205 further includes a bend reduction stop 207 connected to its outside end so that protrudes substantially orthogonally from the eccentric weight 205 for operating as a stop during a high stress drop condition. The bend reduction stop 207 is typically positioned on the eccentric weight 205 such that the bend reduction stop 207 points away from the substrate such as printed circuit board 209 when the eccentric weight 205 is positioned closest to the printed circuit board 209. As seen in FIG. 4, the bend reduction stop 207 is oriented away from the printed circuit board 209 while it is at its closest rotation to the printed circuit board 209.

FIG. 5 illustrates a side and end view of a vibrator counterweight assembly 500 where the shaft 203 is rotated such that the eccentric weight 205 is rotated 180 degrees from that shown in FIG. 4. In this embodiment the bend reduction stop 207 is directly facing the printed circuit board 209. In a fall or other high stress environment, since the eccentric weight is furthest from the printed circuit board 209, the bend reduction stop 207 will operate to prevent substantial damage to the shaft 203. This occurs since the bend reduction stop 207 will contact the printed circuit board 209 before the shaft 203 will flex to the point of unrecoverable damage. Although the shaft 203 may be partially resilient along its longitudinal axis, a high stress condition will cause the shaft to yield with a permanent bend.

FIG. 6 illustrates side and end view of a vibrator counterweight assembly 600 like that in FIG. 5 where the vibrator counterweight assembly 600 has been subject to a drop or other high stress condition. When the internal load is placed on the shaft 203, the shaft and eccentric weight 205 may begin to bend in a direction toward the printed circuit board 209. Before a high amount of permanent damage can be done to the shaft 203, the bend reduction stop 207 may contact the surface of the printed circuit board 209. In most cases, the bend reduction stop 207 will prevent the shaft 203 from flexing or yielding to a point where the bend would allow the bend reduction stop to permanently touch the printed circuit board 207. This allows the eccentric weight 205 and the bend reduction stop 207 to remain clear of the printed circuit board 209 so that it may freely rotate through its full range of motion.

Thus, the present invention is a vibratory counterweight assembly and is arranged such that a counterweight includes a bend reduction stop which is added to its end that prevents the weight from bending into printed circuit board or other housing. By limiting the strain to a level below yield of the motor shaft, the shaft will not presently bent such that the counterweight would contact the printed circuit board during rotation. This allows the vibratory counterweight assembly to continue to operate in the electronic device normally, irrespective of the drop.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

We claim:

1. A vibrator counterweight assembly in an electronic device comprising:
an electric motor and shaft for providing rotational movement adjacent to a substrate;
an eccentric counterweight connected to the electric motor through the shaft;
a bend reduction stop attached to the eccentric counterweight; and
wherein the bend reduction stop works to prevent damage to the shaft during a high stress loading condition on the electronic device.

2. A vibrator counterweight assembly as in claim 1, wherein the bend reduction stop is oriented toward the substrate when the eccentric counterweight rotates farthest from the substrate.

3. A vibrator counterweight assembly as in claim 1, wherein the bend reduction stop is positioned on a side of the eccentric counterweight.

4. A vibrator counterweight assembly as in claim 1, wherein the substrate is a printed circuit board (PCB).

5. A vibrator counterweight assembly as in claim 1, wherein the electronic device is a two-way radio transceiver.

6. A vibrator counterweight assembly for providing tactile annunciation in an electronic device comprising:
a motor and drive shaft mounted on a substrate;
a counterweight eccentrically attached to the drive shaft;
a bend reduction stop attached to the counterweight; and
wherein the bend reduction stop is oriented on the counterweight such that it faces the substrate when the counterweight rotates farthest from the substrate.

7. A vibrator counterweight assembly as in claim 6, wherein the substrate is a printed circuit board (PCB).

8. A vibratory counterweight assembly as claim 6, wherein the bend reduction stop extends from an end of the counterweight.

9. A vibrator counterweight assembly as in claim 6, wherein the bend reduction stop is formed integrally with the counterweight.

10. A vibrator counterweight assembly as in claim 6, wherein the electronic device is a two-way radio transceiver.

11. A method for forming a vibrator counterweight assembly for use with an electronic device comprising the steps of:
rotating a shaft using an electric motor positioned adjacent to a substrate;
connecting an eccentric counterweight to the electric motor through the shaft;
attaching a bend reduction stop to the eccentric counterweight; and
preventing damage to the shaft during a high stress loading condition on the electronic device by allowing the bend reduction stop to contact the substrate.

12. A method for forming a vibrator counterweight assembly for use with an electronic device as in claim 11, further comprising the step of:
Orienting the bend reduction stop toward the substrate when the eccentric counterweight rotates farthest from the substrate.

13. A method for forming a vibrator counterweight assembly for use with an electronic device as in claim 11, further comprising the step of:
positioning the bend reduction stop on a side of the eccentric counterweight.

14. A method for forming a vibrator counterweight assembly for use with an electronic device as in claim 11, wherein the substrate is a printed circuit board (PCB).

15. A method for forming a vibrator counterweight assembly for use with an electronic device as in claim 11, wherein the electronic device is a two-way radio transceiver.
